(19) United States
(12) Patent Application Publication
(10) Pub. No.: US 2026/0206604 A1
(43) Pub. Date: Jul. 16, 2026

(54) ELECTRONIC MODULE AND MANUFACTURING METHOD THEREOF

(71) Applicant: ULTRABAND TECHNOLOGIES, INC., Zhubei City (TW)

(72) Inventors: CHAN-SHIN WU, Zhubei City (TW); Chih-Sheng Yeh, Zhubei City (TW); Shiuan-Jiun Huang, Zhubei City (TW); Kuan-Hsiu Chien, Zhubei City (TW)

(73) Assignee: ULTRABAND TECHNOLOGIES, INC., Zhubei City (TW)

(21) Appl. No.: 19/444,241

(22) Filed: Jan. 9, 2026

Related U.S. Application Data
(60) Provisional application No. 63/745,387, filed on Jan. 15, 2025.

(51) Int. Cl. H10W 44/20; H10W 40/20; H10W 70/05; H10W 70/68; H10W 90/00; H10W 90/10

(52) U.S. Cl. CPC H10W 44/203; H10W 40/233; H10W 70/05; H10W 70/682; H10W 90/10; H10W 90/401; H10W 90/724; H10W 90/727

(57) ABSTRACT

An electronic module and a manufacturing method thereof are provided. The electronic module includes: a glass substrate, including an upper surface and a lower surface; and an integrated passive device (IPD) layer, arranged on at least a portion of the lower surface of the glass substrate, and including at least one IPD. A total inductance value, a total capacitance value, or a total resistance value of the IPD changes in response to laser trimming applied to the IPD through the upper surface of the glass substrate.

### BACKGROUND OF THE INVENTION

### 1. Field of the Invention

The present disclosure relates to a module and a method, and in particular, to an electronic module and a manufacturing method thereof.

### 2. Description of the Related Art

After existing electronic modules applied to, for example, a radio frequency (RF) module, an amplifier module, or a sensor module are packaged and integrated, if characteristics (such as a resistance value, a capacitance value, or an inductance value) of an integrated passive device (IPD) in the electronic module need to be adjusted to improve overall performance of the module and ensure that the performance of the module in a circuit meets a design requirement, a brand-new electronic module may be redesigned, manufactured, and packaged based on a circuit characteristic requirement required by a product employing the electronic module. Alternatively, an uppermost layer of an original electronic module package can be removed first (for example, in a manner such as decap or decoupage), so that an internal IPD can be exposed, and then the IPD (such as a resistor, a capacitor, or an inductor) can be adjusted. After the adjustment, the uppermost layer of the electronic module can be repackaged.

### BRIEF SUMMARY OF THE INVENTION

Although the foregoing manners can adjust an integrated passive device (IPD) in an electronic module, a decap or decoupage process easily causes damage to an internal device/chip or a circuit, and a repackaging process has a low yield. In addition, the foregoing adjustment manners require relatively high costs.

Therefore, the design of adjusting the IPD in the electronic module to avoid the damage to the internal device/chip or the circuit due to the need to perform the decap or the decoupage, to prevent the low yield caused by the repackaging, and to reduce the required costs is critically important.

In view of the above, the present disclosure provides a novel electronic module and a manufacturing method for the electronic module, which can effectively solve the foregoing problems.

The electronic module provided in the present disclosure includes: a glass substrate, including an upper surface and a lower surface; and an integrated passive device (IPD) layer, arranged on at least a portion of the lower surface of the glass substrate, and including at least one IPD. A total inductance value, a total capacitance value, or a total resistance value of the IPD changes in response to laser trimming applied to the IPD through the upper surface of the glass substrate.

In some embodiments, according to the foregoing electronic module, the IPD includes an inductor unit, the inductor unit has a preset inductor laser cutting portion, and the preset inductor laser cutting portion is subjected to the laser trimming to change the total inductance value of the IPD.

In some embodiments, according to the foregoing electronic module, the IPD includes a capacitor unit, the capacitor unit has a preset capacitor cutting portion, and the preset capacitor cutting portion is subjected to the laser trimming to change the total capacitance value of the IPD.

In some embodiments, according to the foregoing electronic module, the IPD includes a resistor unit, the resistor unit has a preset resistor cutting portion, and the preset resistor cutting portion is subjected to the laser trimming to change the total resistance value of the IPD.

In some embodiments, the foregoing electronic module further includes a bypass capacitor layer, arranged on the upper surface of the glass substrate, where a portion of the upper surface of the glass substrate is formed with an opening, and a position of the opening corresponds to a position of the IPD.

In some embodiments, the foregoing electronic module further includes a packaging molded layer, arranged on the upper surface of the glass substrate, where the packaging molded layer and the upper surface of the glass substrate jointly define an opening, and a position of the opening corresponds to a position of the IPD.

In some embodiments, the foregoing electronic module further includes: an active and passive device redistribution layer (RDL), arranged below the glass substrate and the IPD layer, and bonded to the IPD layer; a ceramic substrate, arranged below the active and passive device RDL, and having a metal heat dissipation layer, where the metal heat dissipation layer and the ceramic substrate jointly define a cavity; and a semiconductor chip, arranged in the cavity and located above the metal heat dissipation layer, and electrically connected to the IPD through a conductive interconnection structure.

In some embodiments, the foregoing electronic module further includes a blind via hole, formed in the glass substrate, the IPD layer, and the active and passive device RDL, and extending through the upper surface of the glass substrate to the semiconductor chip for heat dissipation.

In some embodiments, according to the foregoing electronic module, the active and passive device RDL is formed based on a thin film transistor (TFT) process and a panel level packaging (PLP) process.

In some embodiments, according to the foregoing electronic module, the semiconductor chip is a radio frequency (RF) circuit.

The manufacturing method for an electronic module provided in the present disclosure includes the following steps: (A) forming an IPD layer on at least a portion of a lower surface of a glass substrate, where the IPD layer includes at least one IPD, and a total inductance value, a total capacitance value, or a total resistance value of the IPD changes in response to laser trimming applied to the IPD through an upper surface of the glass substrate; (B) forming an active and passive device RDL below the IPD layer and the glass substrate, where the active and passive device RDL is bonded to the IPD layer; (C) forming a metal heat dissipation layer on a ceramic substrate, where the metal heat dissipation layer and the ceramic substrate jointly define a cavity; (D) arranging a semiconductor chip in the cavity and above the metal heat dissipation layer; and (E) bonding the active and passive device RDL to the ceramic substrate, and causing the semiconductor chip to be electrically connected to the IPD through a conductive interconnection structure.

In some embodiments, according to the foregoing manufacturing method, the IPD includes an inductor unit, the inductor unit has a preset inductor laser cutting portion, and the preset inductor laser cutting portion is subjected to the laser trimming to change the total inductance value of the IPD.

In some embodiments, according to the foregoing manufacturing method, the IPD includes a capacitor unit, the capacitor unit has a preset capacitor cutting portion, and the preset capacitor cutting portion is subjected to the laser trimming to change the total capacitance value of the IPD.

In some embodiments, according to the foregoing manufacturing method, the IPD includes a resistor unit, the resistor unit has a preset resistor cutting portion, and the preset resistor cutting portion is subjected to the laser trimming to change the total resistance value of the IPD.

In some embodiments, according to the foregoing manufacturing method, after step (E), the method further includes the following step: (F) arranging a bypass capacitor layer on the upper surface of the glass substrate, where a portion of the upper surface of the glass substrate is formed with an opening, and a position of the opening corresponds to a position of the IPD.

In some embodiments, according to the foregoing manufacturing method, after step (E), the method further includes the following step: (F) arranging a packaging molded layer on the upper surface of the glass substrate, where the packaging molded layer and the upper surface of the glass substrate jointly define an opening, and a position of the opening corresponds to a position of the IPD.

In some embodiments, according to the foregoing manufacturing method, between step (B) and step (C), the method further includes the following step: (F) forming a blind via hole in the glass substrate, the IPD layer, and the active and passive device RDL, where the blind via hole extends through the upper surface of the glass substrate to the semiconductor chip.

In some embodiments, according to the foregoing manufacturing method, the active and passive device RDL includes a TFT structure and an interconnection and packaging structure, and the TFT structure and the interconnection and packaging structure are respectively formed based on a TFT process and a PLP process.

In this way, the present disclosure achieves the following effects: the change of the total inductance value, the total capacitance value, or the total resistance value of the IPD can be implemented by using the design of the glass substrate in combination with the manner of the laser trimming. Therefore, in the present disclosure, a brand-new electronic module does not need to be redesigned, manufactured, and packaged, nor does an uppermost layer of an original electronic module package need to be removed to adjust and repackage the internal IPD. As a result, the damage to the internal device/chip or the circuit caused by the need to perform decap or decoupage can be avoided, the low yield caused by the repackaging can be avoided, and the required costs can be reduced in the present disclosure.

### BRIEF DESCRIPTION OF THE DRAWINGS

FIG. 1 is a schematic structural diagram of an electronic module according to an embodiment of the present disclosure;

FIG. 2 is a schematic structural diagram of an integrated passive device (IPD) including an inductor unit of an electronic module according to an embodiment;

FIG. 3 is a schematic diagram of an equivalent circuit of an inductor unit according to an embodiment;

FIG. 4 is a schematic structural diagram of an inductor unit after being subjected to laser trimming according to an embodiment;

FIG. 5 is a schematic diagram of an equivalent circuit after an inductor unit is subjected to laser trimming according to an embodiment;

FIG. 6 is a schematic structural diagram of an IPD including a resistor unit of an electronic module according to an embodiment;

FIG. 7 is a schematic diagram of an equivalent circuit of a resistor unit according to an embodiment;

FIG. 8A is a schematic structural diagram of an IPD including a capacitor unit of an electronic module according to an embodiment;

FIG. 8B is a schematic diagram of an equivalent circuit of a capacitor unit according to an embodiment;

FIG. 9 is a schematic structural diagram of an electronic module according to another embodiment of the present disclosure;

FIG. 10 is a schematic structural diagram of an electronic module according to yet another embodiment of the present disclosure;

FIG. 11 is a schematic structural diagram of an embodiment derived from the electronic module based on FIG. 1; and

FIG. 12 is a flowchart of a manufacturing method for an electronic module according to the present disclosure.

### DETAILED DESCRIPTION OF THE INVENTION

To fully understand purposes, features, and effects of the present disclosure, the present disclosure is described in detail through the following specific embodiments and the accompanying drawings. The description is as follows. It should be noted herein that a same reference numeral is used for the accompanying drawings with similar or identical structures and operating principles.

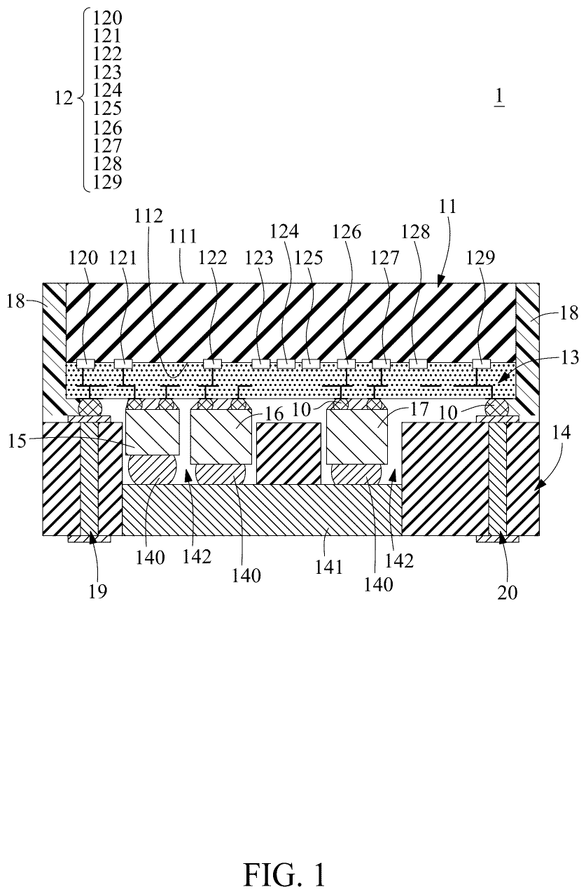

FIG. 1 is a schematic structural diagram of an electronic module 1 according to an embodiment of the present disclosure. The electronic module 1 is formed through packaging and integration. The electronic module 1 includes a glass substrate 11, an integrated passive device (IPD) layer 12, an active and passive device redistribution layer (RDL) 13, a ceramic substrate 14, three semiconductor chips 15, 16, and 17, and two input/output ports 19 and 20 for input/output signals. Left and right sides between the glass substrate 11 and the active and passive device RDL 13 are sealed through a sealing material 18 (for example, plastic, ceramic, metal, or glass). In this embodiment, three semiconductor chips, for example, may be provided, but the present disclosure is not limited thereto. In another embodiment, one semiconductor chip may be provided.

The glass substrate 11 includes an upper surface 111 and a lower surface 112. The glass substrate 11 has optical transparency to a laser wavelength, so that the laser wavelength can penetrate the glass substrate 11 and perform laser trimming on the IPD layer 12, for example, perform laser cutting on a resistor, an inductor, and/or a capacitor.

The IPD layer 12 is arranged on at least a portion of the lower surface 112 of the glass substrate 11. The IPD layer 12 includes at least one IPD. In this embodiment, the IPD layer 12 includes ten IPDs 120-129, but the present disclosure is not limited thereto. The IPD is a circuit formed of a resistor, a capacitor, an inductor, or a combination thereof, and is commonly used for filtering, matching, tuning, or decoupling. For each of the IPDs 120-129, a total inductance value, a total capacitance value, or a total resistance value thereof changes in response to laser trimming (not shown in the figure) applied to the IPD through the upper surface 111 of the glass substrate 11. The laser has a laser light source emitting a laser wavelength capable of penetrating the glass substrate 11, and a type thereof is, for example, a laser such as ultraviolet light (355 nm), green light (532 nm), infrared light (1064 nm), fiber laser (1064 nm), or ultrashort pulse laser (200-1000 nm). The laser is configured to perform laser trimming to precisely remove material and adjust parameters of a passive device, such as an integrated resistor, capacitor, or inductor, which will be described in detail below.

The active and passive device RDL 13 is arranged below the glass substrate 11 and the IPD layer 12, and is bonded to the IPD layer 12. The active and passive device RDL 13 includes a thin film transistor (TFT) structure (not shown in the figure) and an interconnection and packaging structure (not shown in the figure). The TFT structure and the interconnection and packaging structure are respectively formed based on a TFT process and a panel level packaging (PLP) process. In other words, the active and passive device RDL 13 is formed based on the TFT process and the PLP process. Because technologies of the TFT process and the PLP process are known to persons of ordinary skill in the technical field, for the sake of brevity, details are not described herein.

The ceramic substrate 14 is arranged below the active and passive device RDL 13, and has a metal heat dissipation layer 141. A material of the metal heat dissipation layer 141 is, for example, copper (Cu) or a copper tungsten alloy (CuW). The metal heat dissipation layer 141 and the ceramic substrate 14 jointly define two cavities 142, but are not limited thereto. In another embodiment, the metal heat dissipation layer 141 and the ceramic substrate 14 may jointly define only one cavity.

The semiconductor chips 15, 16, and 17 are arranged in the corresponding cavities 142 and located above the metal heat dissipation layer 141, and are electrically connected to the corresponding IPDs (as indicated by reference numerals 121, 122, 126, and 127) through a conductive interconnection structure. The conductive interconnection structure is, for example, a conductive via (or a metal wire) and solder 10. The semiconductor chips 15, 16, and 17 are bonded to the metal heat dissipation layer 141 by silver paste 140 to provide good heat conduction and electrical conduction, so as to rapidly conduct heat generated by the semiconductor chips 15, 16, and 17 to the metal heat dissipation layer 141. The semiconductor chips 15, 16, and 17 are each a radio frequency (RF) circuit, for example, using a power amplifier as an example, but are not limited thereto.

In this embodiment, a detailed circuit structure and a laser trimming manner of IPDs 120-123 and IPDs 125-129 are similar to those of the IPD 124. For the sake of brevity and to avoid describing too much repetitive or similar content, the internal circuit structure of the IPD 124 and the laser trimming performed thereon are described below only by using the IPD as an example, but are not limited thereto.

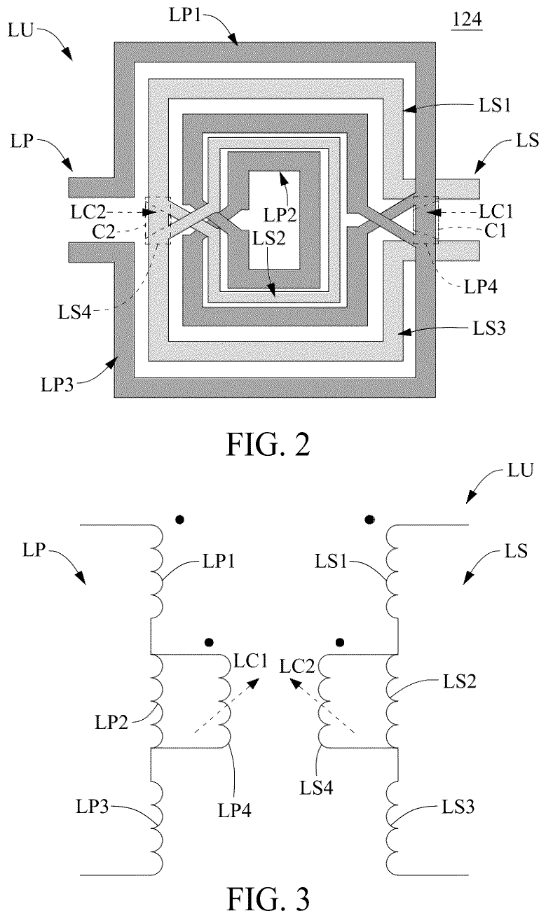

Further, referring to FIG. 2 and FIG. 3, FIG. 2 is a schematic structural diagram of an IPD 124 including an inductor unit LU of an electronic module 1 according to an embodiment. FIG. 3 is a schematic diagram of an equivalent circuit of an inductor unit LU according to an embodiment. The inductor unit LU includes a primary coil LP and a secondary coil LS. The primary coil LP includes coils LP1, LP2, LP3, and LP4, where the coil LP2 and the coil LP4 are connected in parallel. The secondary coil LS includes coils LS1, LS2, LS3, and LS4, where the coil LS2 and the coil LS4 are connected in parallel. A total inductance value of the primary coil LP is a sum of an inductance value of the coil LP1, a parallel inductance value of the coil LP2 and the coil LP4, and an inductance value of the coil LP3 (for example, Lp1+(Lp2//Lp4)+Lp3=0.20 nH, where Lp1-Lp4 are respectively inductance values of the coils LP1-LP4). A total inductance value of the secondary coil LS is a sum of an inductance value of the coil LS1, a parallel inductance value of the coil LS2 and the coil LS4, and an inductance value of the coil LS3 (for example, Ls1+(Ls2//Ls4)+Ls3=0.28 nH, where Ls1-Ls4 are respectively inductance values of the coils LS1-LS4). It should be noted that once an existing inductor unit is completed, adjustment of the inductance value is impossible or difficult to implement. In an actual circuit design, to avoid a frequency offset problem caused by a difference between an inductance value obtained during the process and an actually desired inductance value, the existing technology uses a transistor as a switch to switch the inductance value, to alleviate the frequency offset problem. However, this method causes an existing electronic module to have a relatively large layout area. Therefore, the present disclosure uses the design of the glass substrate 11 in combination with the laser trimming manner to implement the change of the inductance value of the IPD (as indicated by reference numeral 124 in FIG. 1 and FIG. 2), replacing an existing manner of using the transistor as the switch to switch the inductance value. As a result, the layout area of the electronic module can be greatly reduced. Specifically, in this embodiment, the primary coil LP has a preset inductor laser cutting portion C1, and the secondary coil LS has a preset inductor laser cutting portion C2, but are not limited thereto. When the preset inductor laser cutting portions C1 and C2 are subjected to the laser trimming (as indicated by laser cutting LC1 and LC2 in FIG. 2 and FIG. 3), total inductance values of an input and an output of the IPD 124 respectively change.

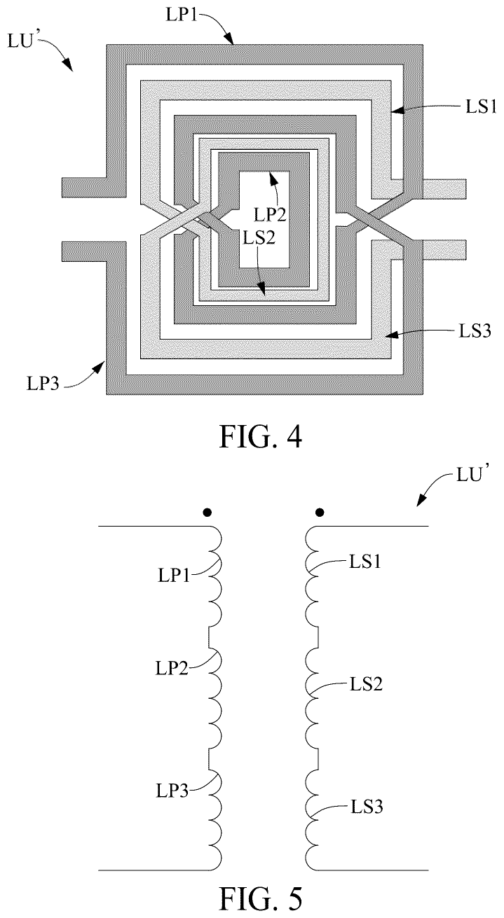

For example, referring to FIG. 4 and FIG. 5, FIG. 4 is a schematic structural diagram of the preset inductor laser cutting portions C1 and C2 of the inductor unit LU after being subjected to laser trimming according to an embodiment (FIG. 4 uses a symbol LU′ to represent the inductor unit after being subjected to the laser trimming). FIG. 5 is a schematic diagram of an equivalent circuit after the preset inductor laser cutting portions C1 and C2 of the inductor unit LU are subjected to the laser trimming according to an embodiment (FIG. 5 uses a symbol LU′ to represent the inductor unit after being subjected to the laser trimming). After being subjected to the laser trimming, the primary coil LP includes series-connected coils LP1, LP2, and LP3, and the secondary coil LS includes series-connected coils LS1, LS2, and LS3. A total inductance value of the primary coil LP is a sum of inductance values of the coils LP1, LP2, and LP3 (for example, Lp1+Lp2+Lp3=0.50 nH), and a total inductance value of the secondary coil LS is a sum of inductance values of the coils LS1, LS2, and LS3 (for example, Ls1+Ls2+Ls3=0.67 nH), so that total inductance values of the input and the output of the IPD 124 respectively increase. In this way, the present disclosure does not need to use a transistor as a switch to switch the inductance value, thereby significantly reducing a layout area of the electronic module.

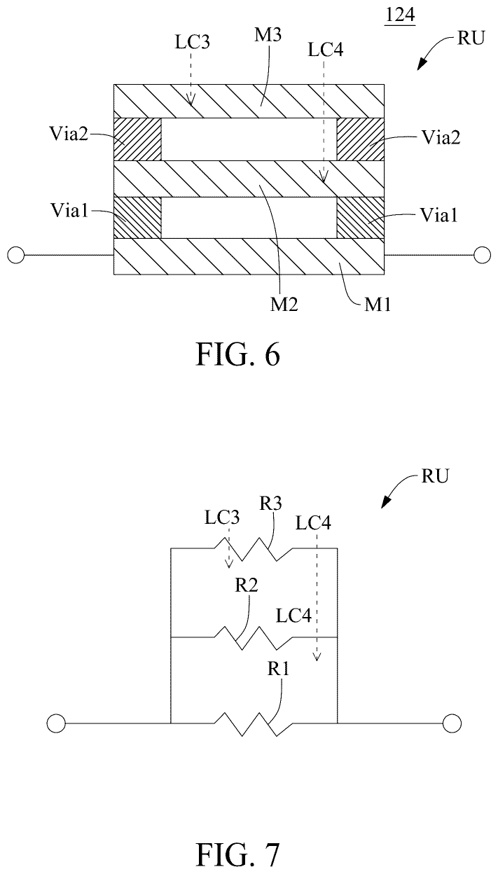

Referring to FIG. 6 and FIG. 7, FIG. 6 is a schematic structural diagram of an IPD 124 including a resistor unit RU of an electronic module 1 according to an embodiment. FIG. 7 is a schematic diagram of an equivalent circuit of a resistor unit RU according to an embodiment. The resistor unit RU is a vertical structure, but is not limited thereto. In another embodiment, the resistor unit RU may also adopt a horizontal structure. The resistor unit RU uses three metal layers M1, M2, and M3 and vias Vial and Via2 to realize a parallel resistor structure (as indicated by reference numerals R1, R2, and R3 in FIG. 7), but is not limited thereto. Resistance values of the resistors R1, R2, and R3 are respectively determined by the metal layers M1, M2, and M3 in FIG. 6. In existing circuit implementations, most of the implementations implement a function of adjustable resistance value in a manner of adding the transistor as a switching switch, but disadvantages of this manner are that the electronic module needs a larger layout area and an additional bias control circuit. Therefore, the present disclosure uses the design of the glass substrate 11 in combination with laser trimming to implement the change of the resistance value of the IPD, replacing an existing manner of using the transistor as the switching switch to adjust the resistance value. In this way, the present disclosure does not need to add the RF switching switch and the additional bias control circuit, which can save a layout area of the electronic module and achieve circuit design optimization. Specifically, in this embodiment, the resistor unit RU has a preset resistor cutting portion (for example, a portion of a resistor film of a metal layer M3 (and/or metal layers M2 and M1)), and the preset resistor cutting portion is subjected to the laser trimming (as indicated by laser cutting LC3 or laser cutting LC4 in FIG. 6 and FIG. 7) to change a total resistance value of the IPD 124. For example, based on a resistance value R=ρ×L/A, where ρ is a material resistivity (fixed), L is an effective length through which a current flows, and A is a cross-sectional area of a conductor, a groove or a serpentine path is etched on the resistor film of the metal layer M3 (or by laser cutting LC4 on the metal layers M3 and M2) through the laser cutting LC3, to reduce an effective conductive path width of the metal layer (that is, an effective cross-sectional area A of the conductor becomes smaller) or increase the effective length (L) through which the current flows, so that the resistance value of the resistor R3 (or the resistors R3 and R2) increases, and the total resistance value of the IPD 124 rises. In this way, the present disclosure does not need to use the RF switching switch and the bias control circuit to adjust the resistance value, thereby saving the layout area of the electronic module.

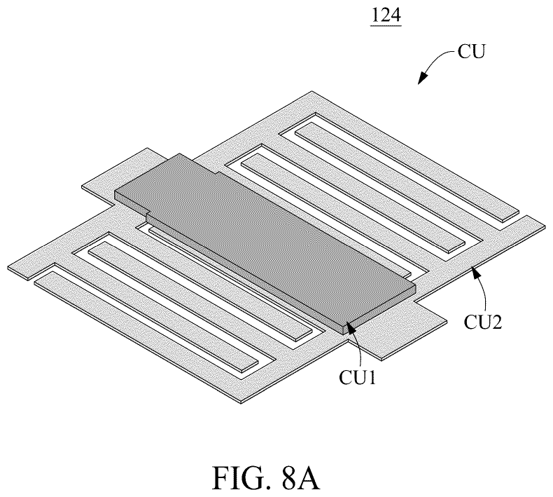

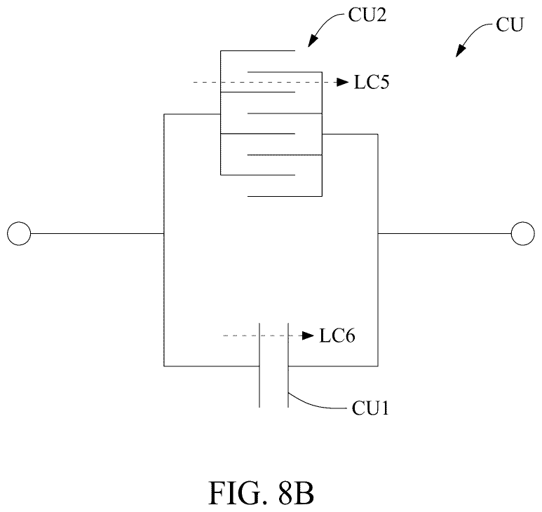

Referring to FIG. 8A and FIG. 8B, FIG. 8A is a schematic structural diagram of an IPD 124 including a capacitor unit CU of an electronic module 1 according to an embodiment. FIG. 8B is a schematic diagram of an equivalent circuit of a capacitor unit CU according to an embodiment. The capacitor unit CU includes a parallel plate capacitor CUI and an interdigital capacitor CU2 connected in parallel with the parallel plate capacitor CU1, but is not limited thereto. In this embodiment, the capacitor unit CU has a preset capacitor cutting portion (for example, a partial region of an electrode of the parallel plate capacitor CUI (and/or some finger ends or some fingers of the interdigital capacitor CU2)). The preset capacitor cutting portion is subjected to laser trimming (as indicated by laser cutting LC5 or laser cutting LC6 in FIG. 8B) to change a total capacitance value of the IPD 124. For example, a capacitance value C=ε×A/d, where ε is a dielectric constant determined by a material, A is an electrode overlap area of a capacitor (or referred to as a plate area), and d is an electrode spacing of the capacitor (or referred to as a plate spacing distance). Therefore, if coarse adjustment is to be performed on the capacitance value of the interdigital capacitor CU2, for example, laser cutting may be used to cut off a segment of each finger end of the interdigital capacitor CU2, to reduce an effective overlap length, or to remove an entire finger/partially break a finger to reduce the electrode overlap area (that is, the capacitance value decreases) for the coarse adjustment. If fine adjustment is to be performed on the capacitance value of the interdigital capacitor CU2, for example, a small chamfer or a groove may be made on the finger end of the interdigital capacitor CU2 to reduce the electrode overlap area for the fine adjustment. If coarse adjustment is to be performed on the capacitance value of the parallel plate capacitor CU1, for example, laser cutting may be used to cut off an entire partial region of an upper electrode of the parallel plate capacitor CUI to reduce the electrode overlap area for the coarse adjustment, and an area reduction directly corresponds to a capacitance value reduction. If fine adjustment is to be performed on the capacitance value of the parallel plate capacitor CU1, for example, a narrow strip scribe or a small hole may be made on an electrode of the parallel plate capacitor CU1, to remove an electrode with a very small area for the fine adjustment. In addition, laser cutting may be used to locally damage a dielectric layer of the parallel plate capacitor CU1 or the interdigital capacitor CU2. In this way, an electrode spacing is increased, and the capacitance value of the parallel plate capacitor CUI or the interdigital capacitor CU2 can also be reduced. Because the capacitance value of the parallel plate capacitor CU1 and/or the interdigital capacitor CU2 decreases, the total capacitance value of the IPD 124 also decreases accordingly.

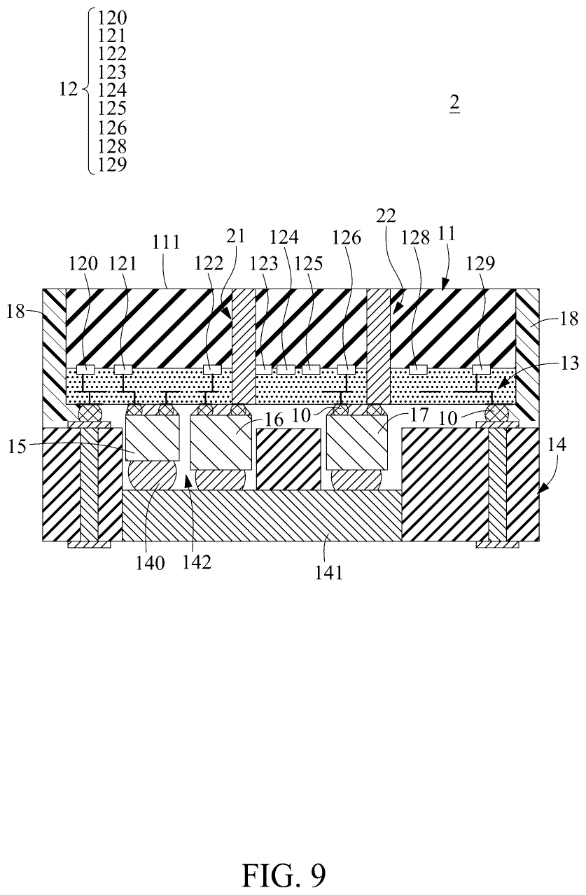

FIG. 9 is a schematic structural diagram of an electronic module according to another embodiment of the present disclosure. An electronic module 2 in FIG. 9 is similar to the electronic module 1 in FIG. 1, and a difference therebetween is that the electronic module 2 further includes two blind via holes 21 and 22, but the present disclosure is not limited thereto. In another embodiment, the electronic module 2 may include only one blind via hole. The blind via holes 21 and 22 are formed in the glass substrate 11, the IPD layer 12, and the active and passive device RDL 13, and respectively extend from the upper surface 111 of the glass substrate 11 to above the semiconductor chips 16 and 17, to dissipate heat generated by the semiconductor chips 16 and 17. In this way, the electronic module 2 has a bidirectional heat conduction path. The blind via holes 21 and 22 can conduct the heat from surfaces of the semiconductor chips 16 and 17 upward, for example, guiding the heat to an upper external heat sink (not shown in the figure). Meanwhile, the metal heat dissipation layer 141 below conducts heat from bottom surfaces of the semiconductor chips 16 and 17 downward, for example, transmitting the heat to a substrate or a module housing (not shown in the figure), thereby allowing the semiconductor chips 16 and 17 to significantly reduce a junction temperature (Tj), achieve uniform heat distribution, and have a longer lifetime, thereby improving overall reliability of the electronic module 2.

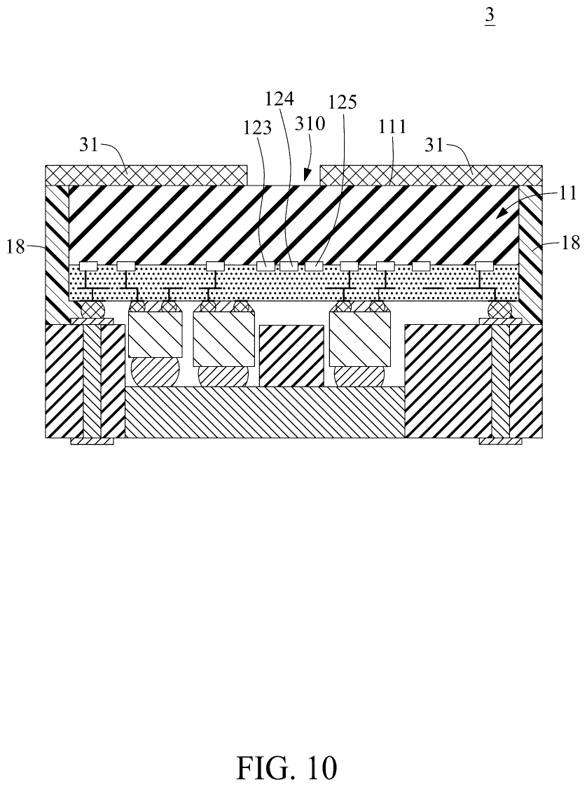

FIG. 10 is a schematic structural diagram of an electronic module according to yet another embodiment of the present disclosure. An electronic module 3 in FIG. 10 is similar to the electronic module 1 in FIG. 1, and a difference therebetween is that the electronic module 3 further includes a packaging molded layer 31. The packaging molded layer 31 is arranged on the upper surface 111 of the glass substrate 11, and the packaging molded layer 31 and the upper surface 111 of the glass substrate 11 jointly define an opening 310. A position of the opening 310 corresponds to a position of an IPD (for example, the IPDs 123, 124, and 125 to be subjected to laser trimming), but is not limited thereto. In this way, the laser can penetrate from the upper surface 111 of the glass substrate 11 to the IPDs 123, 124, and 125 through the opening 310 to perform laser trimming. In this embodiment, the packaging molded layer 31 is a protective layer formed by molding, for example, an epoxy resin on the upper surface 111 of the glass substrate 11 and the upper surface of the sealing material 18. The packaging molded layer is used to, for example, prevent an external environmental factor from causing damage to an internal circuit, thereby helping maintain reliability of the electronic module 3.

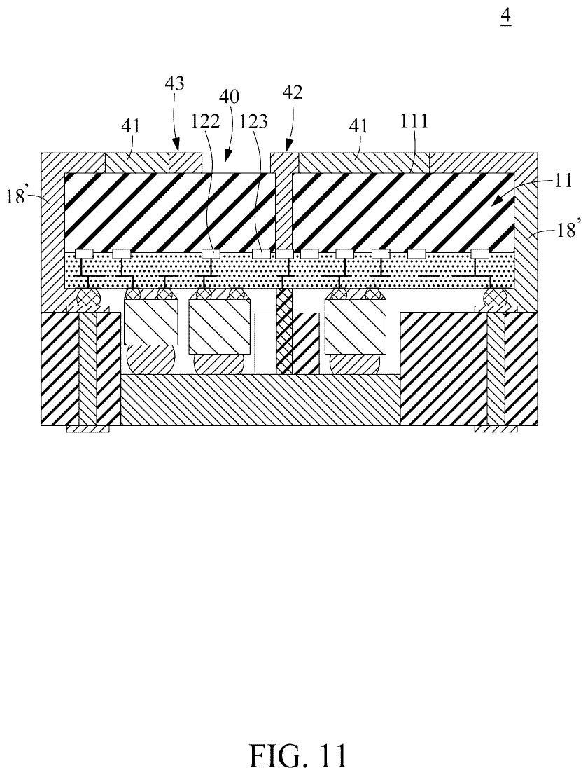

FIG. 11 is a schematic structural diagram of an embodiment derived from the electronic module 1 according to the present disclosure. An electronic module 4 in FIG. 11 is similar to the electronic module 1 in FIG. 1, and the main differences therebetween are that a conductive vias 18′is used to replace the sealing material 18 in FIG. 1, and the electronic module 4 further includes a bypass capacitor layer 41, a blind via hole 42, and a conductor 43. The bypass capacitor layer 41, the blind via hole 42, and the conductor 43 are all arranged on the upper surface 111 of the glass substrate 11, but are not limited thereto. A portion of the upper surface 111 of the glass substrate 11 is formed with an opening 40 (for example, jointly defined by a portion of the upper surface 111 of the glass substrate 11, the blind via hole 42, and the conductor 43). A position of the opening 40 corresponds to a position of an IPD (for example, the IPDs 122 and 123 to be subjected to laser trimming), but is not limited thereto. In this way, the laser can penetrate from the upper surface 111 of the glass substrate 11 to the IPDs 122 and 123 through the opening 40 to perform laser trimming. In this embodiment, the bypass capacitor layer 41, for example, can be used to suppress power supply noise and reduce external electromagnetic interference. Compared with an existing configuration in which a bypass capacitor layer is directly arranged on a semiconductor chip, which has a disadvantage of wasting horizontal space due to a large area occupied by the bypass capacitor layer, the bypass capacitor layer 41 is directly arranged on the upper surface 111 of the glass substrate 11 in the present disclosure, and is realized by layered fabrication with the entire layer serving as a bypass capacitor, thereby reducing required horizontal space.

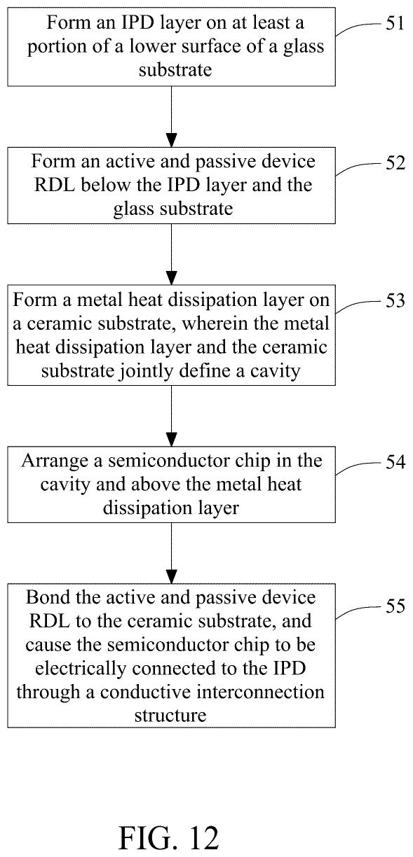

FIG. 12 is a flowchart of a manufacturing method for the foregoing electronic module. In the present disclosure, the manufacturing method for the electronic module 1 includes the following steps 51-55, but is not limited thereto.
Step 51: Form an IPD layer 12 on at least a portion of a lower surface 112 of a glass substrate 11. The IPD layer 12 includes at least one IPD (for example, at least one of reference numerals 120-129 in FIG. 1). A total inductance value, a total capacitance value, or a total resistance value of the IPD changes in response to laser trimming applied to the IPD through the upper surface 111 of the glass substrate 11.
Step 52: Form an active and passive device RDL 13 below the IPD layer 12 and the glass substrate 11.
Step 53: Form a metal heat dissipation layer 141 on a ceramic substrate 14 (for example, a lower surface thereof), where the metal heat dissipation layer 141 and the ceramic substrate 14 jointly define a cavity 142.
Step 54: Arrange semiconductor chips 15-17 in the cavity 142 and above the metal heat dissipation layer 141.
Step 55: Bond the active and passive device RDL 13 to the ceramic substrate 14, and cause the semiconductor chips 15-17 to be electrically connected to the IPD (for example, indicated by reference numerals 121, 122, and 126 in FIG. 1) through a conductive interconnection structure.

In some embodiments of the foregoing manufacturing method for an electronic module, between step 52 and step 53, the method further includes the following step (not shown in the figure): forming blind via holes 21 and 22 in the glass substrate 11, the IPD layer 12, and the active and passive device RDL 13, where the blind via holes 21 and 22 extend through the upper surface 111 of the glass substrate 11 to the semiconductor chips 16 and 17, to implement a portion of the electronic module 2 shown in FIG. 9.

In some embodiments of the foregoing manufacturing method for an electronic module, after step 55, the method further includes the following step (not shown in the figure): arranging a packaging molded layer 31 on the upper surface 111 of the glass substrate 11, where the packaging molded layer 31 and the upper surface 111 of the glass substrate 11 jointly define an opening 310, and a position of the opening 310 corresponds to positions of the IPDs 123-125, to implement a portion of the electronic module 3 shown in FIG. 10.

In some embodiments of the foregoing manufacturing method for an electronic module, after step 55, the method further includes the following steps (not shown in the figure): using a conductive via (as indicated by the reference numeral 18′ in FIG. 11) to replace the sealing material (as indicated by the reference numeral 18 in FIG. 1) 18, and arranging the bypass capacitor layer 41 on the upper surface 111 of the glass substrate 11, where a portion of the upper surface 111 of the glass substrate 11 is formed with an opening 40, and a position of the opening 40 corresponds to positions of the IPDs 122 and 123, to implement a portion of the electronic module 4 shown in FIG. 11.

Based on the above, in addition to having the foregoing effects, compared with the prior art, the electronic module and the manufacturing method thereof in the present disclosure can implement changes in the total inductance value, the total capacitance value, or the total resistance value of the IPD by using the design of the glass substrate 11 in combination with the manner of laser trimming. Therefore, in the present disclosure, a brand-new electronic module does not need to be redesigned, manufactured, and packaged, or an uppermost layer of an original electronic module package does not need to be removed first, to adjust and repackage the internal IPD. As a result, damage to the internal device/chip or the circuit caused by the need to perform decap or decoupage can be avoided, a low yield caused by the repackaging can be avoided, and the required costs can be reduced in the present disclosure. In addition, a matching network is modified in the manner of laser trimming/cutting of the IPD, so that a product can be directly produced.

However, the above are only embodiments of the present disclosure and should not be used to limit the scope of implementation of the present disclosure. All simple equivalent changes and modifications made based on the scope of the patent application of the present disclosure and the content of the patent specification still fall within the scope of the patent of the present disclosure.

What is claimed is:

1. An electronic module, comprising:
a glass substrate, comprising an upper surface and a lower surface; and
an integrated passive device (IPD) layer, arranged on at least a portion of the lower surface of the glass substrate, and comprising at least one IPD, wherein a total inductance value, a total capacitance value, or a total resistance value of the IPD changes in response to laser trimming applied to the IPD through the upper surface of the glass substrate.

2. The electronic module according to claim 1, wherein the IPD comprises an inductor unit, the inductor unit has a preset inductor laser cutting portion, and the preset inductor laser cutting portion is subjected to the laser trimming to change the total inductance value of the IPD.

3. The electronic module according to claim 1, wherein the IPD comprises a capacitor unit, the capacitor unit has a preset capacitor cutting portion, and the preset capacitor cutting portion is subjected to the laser trimming to change the total capacitance value of the IPD.

4. The electronic module according to claim 1, wherein the IPD comprises a resistor unit, the resistor unit has a preset resistor cutting portion, and the preset resistor cutting portion is subjected to the laser trimming to change the total resistance value of the IPD.

5. The electronic module according to claim 1, further comprising:
bypass capacitor layer, arranged on the upper surface of the glass substrate, wherein a portion of the upper surface of the glass substrate is formed with an opening, and a position of the opening corresponds to a position of the IPD.

6. The electronic module according to claim 1, further comprising:
packaging molded layer, arranged on the upper surface of the glass substrate, wherein the packaging molded layer and the upper surface of the glass substrate jointly define an opening, and a position of the opening corresponds to a position of the IPD.

7. The electronic module according to claim 1, further comprising:
active and passive device redistribution layer (RDL), arranged below the glass substrate and the IPD layer, and bonded to the IPD layer;
ceramic substrate, arranged below the active and passive device RDL, and having a metal heat dissipation layer, wherein the metal heat dissipation layer and the ceramic substrate jointly define a cavity; and
semiconductor chip, arranged in the cavity and located above the metal heat dissipation layer, and electrically connected to the IPD through a conductive interconnection structure.

8. The electronic module according to claim 7, further comprising:
a blind via hole, formed in the glass substrate, the IPD layer, and the active and passive device RDL, and extending through the upper surface of the glass substrate to the semiconductor chip for heat dissipation.

9. The electronic module according to claim 7, wherein the active and passive device RDL is formed based on a thin film transistor (TFT) process and a panel level packaging (PLP) process.

10. The electronic module according to claim 7, wherein the semiconductor chip is a radio frequency (RF) circuit.

11. A manufacturing method for an electronic module, comprising the following steps:
(A) forming an IPD layer on at least a portion of a lower surface of a glass substrate, wherein the IPD layer comprises at least one IPD, and a total inductance value, a total capacitance value, or a total resistance value of the IPD changes in response to laser trimming applied to the IPD through an upper surface of the glass substrate;
(B) forming an active and passive device RDL below the IPD layer and the glass substrate, wherein the active and passive device RDL is bonded to the IPD layer;
(C) forming a metal heat dissipation layer on a ceramic substrate, wherein the metal heat dissipation layer and the ceramic substrate jointly define a cavity;
(D) arranging a semiconductor chip in the cavity and above the metal heat dissipation layer; and
(E) bonding the active and passive device RDL to the ceramic substrate, and causing the semiconductor chip to be electrically connected to the IPD through a conductive interconnection structure.

12. The manufacturing method according to claim 11, wherein the IPD comprises an inductor unit, the inductor unit has a preset inductor laser cutting portion, and the preset inductor laser cutting portion is subjected to the laser trimming to change the total inductance value of the IPD.

13. The manufacturing method according to claim 11, wherein the IPD comprises a capacitor unit, the capacitor unit has a preset capacitor cutting portion, and the preset capacitor cutting portion is subjected to the laser trimming to change the total capacitance value of the IPD.

14. The manufacturing method according to claim 11, wherein the IPD comprises a resistor unit, the resistor unit has a preset resistor cutting portion, and the preset resistor cutting portion is subjected to the laser trimming to change the total resistance value of the IPD.

15. The manufacturing method according to claim 11, wherein after step (E), the method further comprises the following step:
(F) arranging a bypass capacitor layer on the upper surface of the glass substrate, wherein a portion of the upper surface of the glass substrate is formed with an opening, and a position of the opening corresponds to a position of the IPD.

16. The manufacturing method according to claim 11, wherein after step (E), the method further comprises the following step:
(F) arranging a packaging molded layer on the upper surface of the glass substrate, wherein the packaging molded layer and the upper surface of the glass substrate jointly define an opening, and a position of the opening corresponds to a position of the IPD.

17. The manufacturing method according to claim 11, wherein between step (B) and step (C), the method further comprises the following step:
(F) forming a blind via hole in the glass substrate, the IPD layer, and the active and passive device RDL, wherein the blind via hole extends through the upper surface of the glass substrate to the semiconductor chip.

18. The manufacturing method according to claim 11, wherein the active and passive device RDL comprises a TFT structure and an interconnection and packaging structure, and the TFT structure and the interconnection and packaging structure are respectively formed based on a TFT process and a PLP process.
